(19) United States
(12) Patent Application Publication
(10) Pub. No.: US 2024/0188443 A1
(43) Pub. Date: Jun. 6, 2024

(54) GRAPHENE ELECTRODE PRODUCTION BY ELECTROSPRAY METHOD AND USAGE IN NANOGENERATORS

(71) Applicant: BURSA TEKNIK ÜNIVERSITESI REKTÖRLÜGÜ, Bursa (TR)

(72) Inventors: Ayse BEDELOGLU, Nilüfer, Bursa (TR); Ömer Faruk ÜNSAL, Inegöl, Bursa (TR); Yasin ALTIN, Kestel, Bursa (TR)

(21) Appl. No.: 18/550,107

(22) PCT Filed: Mar. 10, 2022
(86) PCT No.: PCT/TR2022/050214

§ 371 Date: Sep. 11, 2023

(30) Foreign Application Priority Data
Mar. 16, 2021 (TR) 2021/004874

(51) Int. Cl. H10N 30/06; C01B 32/194; C01B 32/198; C01B 32/23; D04H 1/4318; D04H 1/4382; D04H 1/728; D06M 10/06; D06M 11/63; D06M 11/76; D06M 101/22; H10N 30/00; H10N 30/098; H10N 30/30; H10N 30/857; H10N 30/87

(52) U.S. Cl. CPC H10N 30/06; C01B 32/194; C01B 32/198; C01B 32/23; D04H 1/4318; D04H 1/43838; D04H 1/728; D06M 10/06; D06M 11/63; D06M 11/76; H10N 30/098; H10N 30/1061; H10N 30/30; H10N 30/857; H10N 30/878; C01P 2004/03; D06M 2101/22; D06M 2200/00; D10B 2505/00

(57) ABSTRACT

The invention relates to an electrode containing reduced graphene oxide nanofiber surface (25) with increased mechanical stress resistance, produced by electrospray method to increase efficiency by using in piezoelectric nanogenerators (40) with graphene electrodes.

### FIELD OF THE INVENTION

Invention is related to electrospray-fabricated graphene electrodes for nanofiber-based nanogenerators.

### BACKGROUND

Nanogenerators are the devices that provided to recover of waste energy, which is resulted from non-efficient usage of mechanical or thermal energy sources. Nanogenerators work with three different mechanisms: piezoelectric conversion, triboelectric conversion, and pyroelectric conversion.

Piezoelectric materials generates electrical charge on different regions of their crystal or macromolecular structure. Total energy density that the system will be generated is directly proportional to surface area of material. Because of that electrospun piezoelectric nanofibers are the common materials for piezoelectric nanogenerator fabrication. The secondary important point for nanogenerators is the electrodes. The produced electrical charge should be conducted through the piezoelectric material to convenient electronical component for storage, usage, or transformation.

Graphene is a carbon-based material, which is commonly used in smart and innovative electronics. High electrical conductivity and unique mechanical properties of graphene are the main motivations of graphene use in nanogenerators.

In graphene use on different surfaces, graphene coating method (spraying, dipping, spinning etc.) is quite important and affects the performance of device directly. The most common methods of graphene coatings for nanofiber-based structures are chemical vapor deposition and dip-coating methods. Cost, production difficulty, surface incompatibility are most common problems for these methods. These methods also bring some environmental risks like toxic gas releasing and excessive energy consumption.

Graphene oxide (GO) is the material that oxidized groups (such as —COOH, —CO, —OH) covalently bonded onto the graphene flakes. Majority of oxidized groups gets removed from graphene surface with the reduction process and a structure emerges with high electrical conductivity and high carbon content, which is named as reduced graphene oxide. According to literature, reduction process of graphene oxide is usually performed with thermal and chemical methods.

The following documents were encountered during the preliminary patent search.

The document with CN107623068B patent application number mentioned a rubber-based piezoelectric nanomaterial containing nanocomposite film with conductive particle based interdigital electrodes onto the piezoelectric film surface. In this patent document, surface coating problems are tried to be overcome by dip coating method with polymer addition into the electrode material mixture.

The document with CN111129466A patent application number mentioned that spray coating of polymer, graphene and carbon nanotube containing coating material onto the electrodes of lithium-ion batteries. The mentioned coating application resulted with a homogeneous coating onto the battery electrodes, however adhesion between battery material and electrodes was not strong as required.

The document with WO2020080831A1 patent application number mentioned the coating of two layered electrode application. According to document, the layers with different electrical conductivities provide better electrical and mechanical properties. In the document, In the study, which aims to reduce the problems of adhesion and homogenization thanks to the two-layer coating, the suitability for nanogenerators or the areas of electrodes sensitive to electrical potential such as nanogenerators are not mentioned.

The document with WO2013094840A1 patent application number mentioned three-dimensional transparent graphene electrode production with electrospray method. In the method used, environments that are not suitable for nanogenerators are used and the appropriate sensitivity for nanogenerators is not mentioned.

As the result, all the problems which are mentioned above made mandatory to make an innovation on this area.

### PURPOSE OF THE INVENTION

The presented invention aims to overcome the mentioned problems and innovate in the related technical field.

Main purpose of invention introduce the advantages on nanogenerator efficiency of tightly wrapped nanofibers by graphene sheets.

another purpose of invention is prove the better mechanical properties thanks to mentioned tightly wrapped structure.

### BRIEF SUMMARY OF THE INVENTION

In order to realize all the objectives mentioned above and which will emerge from the detailed description below, the present invention is a graphene-containing electrode and the method of producing of the electrode, produced using the electrospray method for use in nanofiber-based piezoelectric nanogenerators.

A production method of electrode which is containing reduced graphene oxide for use in piezoelectric generators comprising following steps;
producing graphene oxide coated nanofiber surface with the graphene oxide solution in the graphene oxide feeding syringe, on the PVDF (Poly vinylidene fluoride) nanofiber plate formed on the rotating drum by electrospray method, with the help of a high voltage source in the voltage range of 10-40 kV,
soaking mentioned graphene oxide coated nanofiber surface in hydrazine hydrate solution fort the conversion of the graphene oxide coated nanofiber surface to the reduced graphene oxide coated nanofiber surface after the graphene oxide coating process.

An electrode production method comprising; exposing the PVDF nanofiber plate formed on the rotating drum to the solution from a distance of 8 cm with a solution feed rate of 30 mL/h in the potential difference provided by the high voltage source in the step of producing the graphene oxide coated nanofiber surface by electrospray method.

An electrode production method comprising; in the graphene oxide coating step with the electrospray method on the PVDF nanofiber plate, the graphene oxide solution in the syringe is containing the graphene oxide solution that is mixed with 0.5 mg/ml of graphene oxide produced by Hummers' method in a solvent containing deionized water and 2-propanol by volume.

An electrode production method comprising; said Hummer's method is comprising steps of;
dispersing 1 gram of graphite powder into the 120 mL of concentrated sulfuric acid and 13.3 mL of concentrated phosphoric acid mixture,
adding 6 grams of potassium permanganate into graphite-acid mixture and maintaining of the reaction for 12 hours at 50° C.,
pouring 120 mL of ice on the mixture obtained after 12 hours,
adding 1 ml of hydrogen peroxide in order to eliminate the excess amount of potassium permanganate,
separating solid graphene oxide and supernatant by centrifugation,
repeating the centrifugation process at least once, by washing the solid material separately with ethyl alcohol and HCl between the centrifugation processes.

An electrode production method comprising; said hydrazine hydrate solution, which enables the conversion of the graphene oxide coated nanofiber surface to the reduced graphene oxide coated nanofiber surface after the graphene oxide coating process, is 0.3 molar.

An electrode which increases the mechanical stress resistance of the reduced graphene oxide-coated nanofibrous structure as a result of the reduced graphene oxide-coated nanofibrous structure tightly wrapping the PVDF nanofibrous structure of the reduced graphene oxide coating and increases the output voltage and output current obtained from nanogenerators by the same tightly wrapping structure is used to increase the interface area of the PVDF nanofiber surface with reduced graphene oxide coating.

A piezoelectric nanogenerator comprises the electrode socket in the middle of separator paper positioned between two aluminum electrodes and an electrode placed in the said electrode socket.

### BRIEF DESCRIPTION OF THE FIGURES

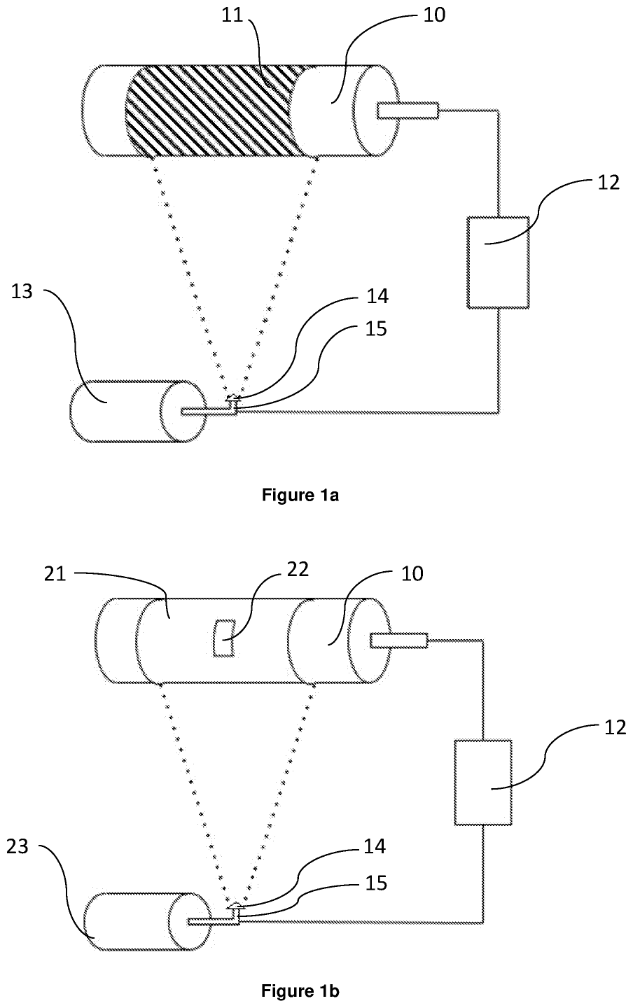

Diagram of nanofiber coating with electrospray method and diagram of coating of graphene oxide onto the nanofiber mat were given in FIGS. 1a and 1b, respectively.

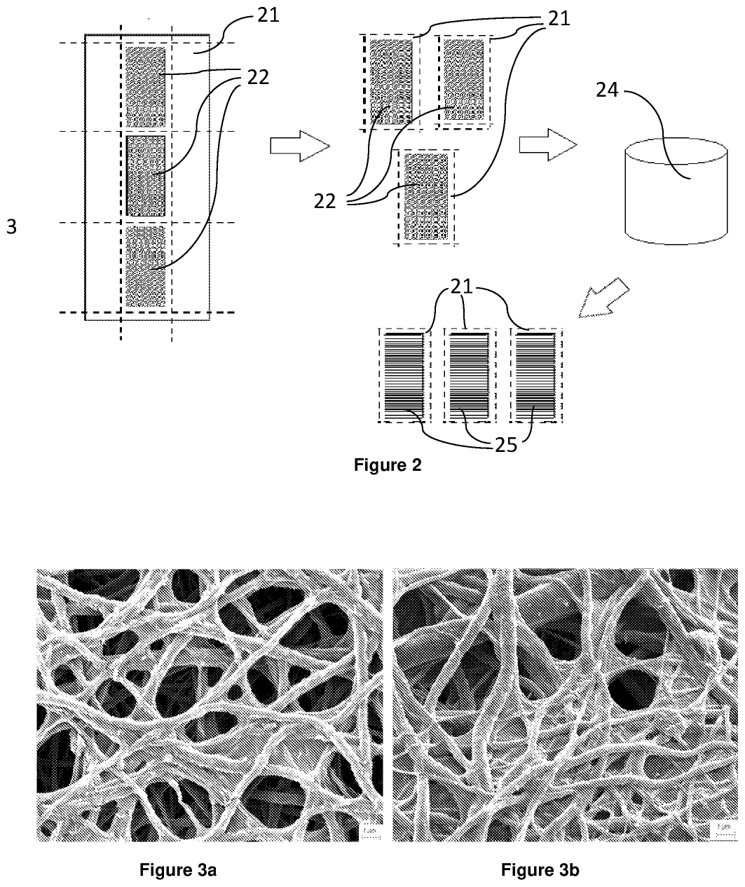

Diagram of chemical reduction of graphene oxide to reduced graphene oxide procedure is given in FIG. 2.

Scanning electron microscopy (SEM) images of before and after chemical reduction of coated graphene oxide flakes onto the nanofibers were given in FIGS. 3a and 3b, respectively.

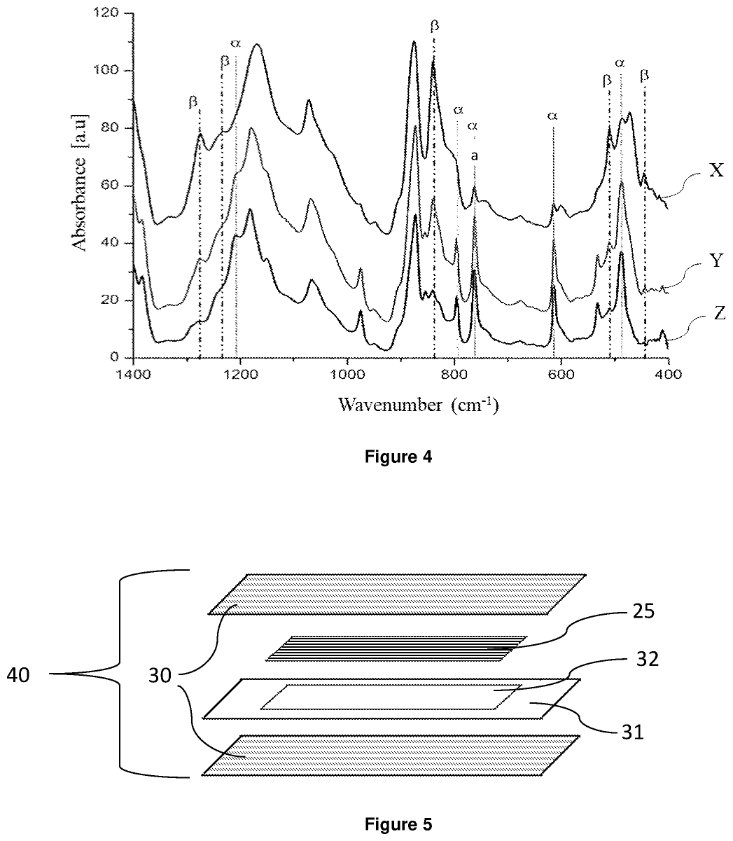

Fourier Transform infrared spectroscopy (FT-IR) results of powder PVDF, graphene oxide coated PVDF nanofiber, and reduced graphene oxide coated PVDF nanofiber were given in FIG. 4.

Diagram of laminated nanogenerator device fabrication was given in FIG. 5.

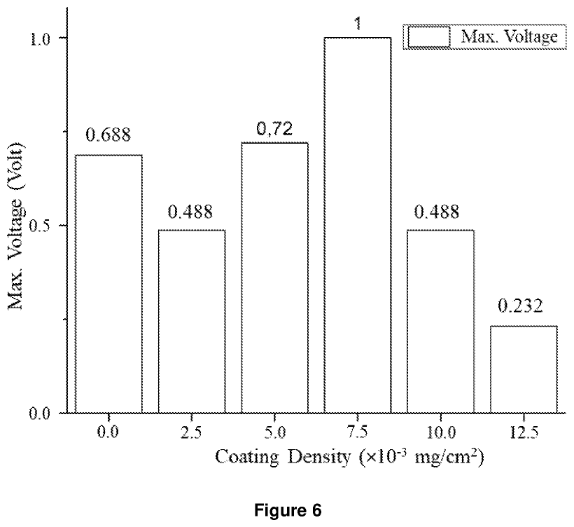

Maximum output voltage diagram of piezoelectric nanogenerators, which are produced with different amounts of graphene oxide, in FIG. 6.

Drawings do not necessarily need to be scaled, and details not necessary for understanding the present invention may be omitted. Furthermore, elements that are at least substantially identical or have at least substantially identical functions are denoted by the same number.

### Description of the Reference Numbers in Figures

10. Rotating drum
11. PVDF nanofiber mat
12. High voltage source
13. PVDF solution feeding syringe
14. Nozzle
15. Solution transfer tube
21. PET foil-based mask
22. Graphene oxide coated nanofiber surface
23. Graphene oxide solution feeding syringe
24. Hydrazine hydrate solution
25. Reduced graphene oxide coated nanofiber surface
30. Aluminum electrode
31. Spacer paper
32. Graphene electrode socket
40. Piezoelectric nanogenerator with graphene electrode

### DETAILED DESCRIPTION OF THE INVENTION

In this detailed explanation, the subject of the invention, “production of graphene electrodes by electrospray method and its use in nanogenerators” is explained only with examples that will not have any limiting effect so that the subject can be better understood.

The subject of the invention relates to the graphene-containing electrode produced using the electrospray method for use in nanofiber-based piezoelectric nanogenerators (40).

Schematic illustration of electrospinning which is used to coat PVDF (Poly vinylidene fluoride) nanofiber mats (11), was shown in FIG. 1a to better understand the process. The method includes a PVDF nanofiber mat (11), rotating drum (10), PVDF solution feeding syringe (13), solution transfer tube (15) connected mentioned PVDF solution feeding syringe (13), a nozzle (14) at the end of the solution transfer tube (15) allows the sprayed solution to be aimed at the rotating drum (10), and a high voltage source (12) that accelerates the solution coming out of the nozzle (14) to reach the rotating drum (10).

In order to form a PVDF nanofiber layer by electrospinning, the PVDF solution in the PVDF solution feeding syringe (13) was transferred by solution transfer tube (15) to the nozzle (14), then the solution was electrospun onto the rotating drum (10) in an accelerated manner thanks to the high voltage source (12).

In the preparation of the PVDF polymer solution in the syringe (13), a mixture of acetone and dimethylformamide at a ratio of 2/1 by mass was used as a solvent and a polymer solution containing 10% poly(vinylidene fluoride) by mass was prepared. For the PVDF nanofiber layer formation process by electrospinning, 23 kV applied voltage, 15 cm nozzle-to-collector distance, and 4 ml/h feed rate were determined as optimum electrospinning conditions. The resulting structure is in the form of a nonwoven polymeric surface with fiber diameters between 200 nm and 230 nm and thicknesses between 130 and 210 μm.

In FIG. 1b, a diagram including electrospray coating of graphene oxide on the PVDF nanofiber mat (11) is given for a better understanding of the graphene oxide coating process with electrospray. The method includes a rotating drum (10) that is used to form a graphene oxide coated nanofiber surface (22), by coating graphene oxide on the PVDF nanofiber mat (11), PET foil mask (21) with rectangular space to be used as a template on the rotating drum (10), graphene oxide solution feeding syringe (23) which contains graphene oxide solution, solution transfer tube (15) connected mentioned graphene oxide solution feeding syringe (23), a nozzle (14) at the end of the solution transfer tube (15) allows the sprayed solution to be aimed at the rotating drum (10), and a high voltage source (12) that accelerates the solution coming out of the nozzle (14) to reach the rotating drum (10).

Graphene oxide solution which is used in the electrospraying process comes from the graphene oxide solution feeding syringe (23) to the nozzle (14) with the solution transfer tube (15) and is sprayed in an accelerated manner thanks to the high voltage source (12), forming a coating on the surface of the PVDF nanofiber mat (11) placed in the rectangular space in the pet foil mask (21) on the rotating drum (10).

The graphene oxide solution in the graphene oxide solution feeding syringe (23) contains graphene oxide at a concentration of 0.5 mg/mL in a solvent consisting of a 2:1 mixture of deionized water and 2-propanol by volume.

The graphene oxide used in the solution was synthesized from graphite powder by the improved Hummers' method. According to the developed Hummers' method, after 1 g of graphite powder was dispersed in a mixture of 120 mL of concentrated H₂SO₄ and 13.3 mL of concentrated H₃PO₄, 6 g of KMnO₄ was added for the oxidation process and the reaction was continued at 50° C. for 12 hours. After 12 hours, the resulting mixture was poured onto 120 ml of ice and finally, 1 mL of H₂O₂ was added to eliminate excess KMnO₄. The mixture was centrifuged to separate the solid graphene oxide and the supernatant. For centrifugation, the solid phase was washed separately with ethyl alcohol and HCl and centrifuged again. It was washed about 15 times with distilled water and centrifuged, and then the synthesized graphene oxide was dried for use.

The graphene oxide solution in the syringe, electrospraying process was carried out with a solution feed rate of 30 mL/h, a distance of 8 cm, an applied voltage of 33-37 kV.

In FIG. 2, the schematic representation of the reduction process of the graphene oxide coated nanofiber surface (22) is given, which describes the conversion of the graphene oxide coated nanofiber surface (22) to the reduced graphene oxide coated nanofiber surface (25) after the graphene oxide coating process with electrospray. Graphene oxide-coated nanofiber surface (22) mats were taken into 0.3 M hydrazine hydrate solution (24) and subjected to reduction at 95° C. for 3 hours, reduced graphene oxide-coated nanofiber surface (25) mats were taken from the reaction balloon after 3 hours. And then they were washed with distilled water and left to dry.

It has been confirmed by SEM (scanning electron microscopy) images that the sprayed graphene oxide solution successfully covers the surface of the PVDF nanofiber mats (11) after the graphene oxide coating process by electrospraying. In addition, the pre-reduction (FIG. 3a) and post-reduction (FIG. 3b) states of the graphene coating were also observed in the SEM images, and it was determined that the reduced graphene oxide by the reduction process adhered more firmly to the PVDF nanofiber mat (11) surface. With this adhesion, the interface area increases, so the output voltage and output current, ie efficiency, obtained from the piezoelectric nanogenerator with graphene electrodes (40) increases.

FTIR (Fourier Transform Infrared Spectroscopy) spectrums of PVDF powder (X), PVDF nanofiber (Y), and reduced nanofiber (Z) given in FIG. 4 are given. Since no covalent bond is formed between PVDF and graphene, it is not easy to visualize it with FTIR. In the spectrum, the peaks marked with α indicate the α crystalline phase, and the peaks marked with β indicate the β crystalline phase. What can be understood from the FTIR spectrum is that the powder PVDF material passes into the β crystal phase while it becomes nanofibers, and when reduction with hydrazine is made, the β phase peak intensities increase.

FIG. 5 shows the diagram describing the layers of the piezoelectric nanogenerator with graphene electrode (40). The mentioned piezoelectric nanogenerator with graphene electrode (40) contains separator paper (31) with a rectangular graphene electrode slot (32), a reduced graphene oxide coated nanofiber surface (25) obtained by a method according to any of the mentioned in the detailed description, and two aluminum electrodes (30) that take the above-mentioned components between it.

In FIG. 6, voltage outputs of piezoelectric generators with graphene electrode (40) during mechanical bending was recorded with the help of an oscilloscope. The reduced graphene oxide-coated nanofiber surface (25) used in the production of nanogenerators as electrodes were produced as a result of the reduction of graphene oxide-coated nanofiber surfaces (25) at 3 different concentrations such as 0, 29.4×10⁻³, 58.8×10⁻³, 88.2×10⁻³, 117.6×10⁻³, and 147.0×10⁻³ mg/cm². The maximum voltage was measured in the structure containing reduced graphene oxide coated nanofiber surface (25), each surface coated with 88.2×10⁻³ mg/cm² graphene oxide. Graphene oxide was sprayed onto an area of 10 cm×38 cm. However, since a pet foil mask (21) is placed on the nanofiber surface during coating, the covered areas are limited to unmask areas that is 2.5 cm×8.5 cm.

The scope of protection of the invention is specified in the attached claims and cannot be limited to what is described in this detailed explanation for exemplary purposes. Because it is clear that a person skilled in science can present similar embodiments in the light of what has been explained above without departing from the main theme of the invention.

1. A production method of an electrode containing reduced graphene oxide for use in piezoelectric generators comprising the following steps:
producing a graphene oxide coated nanofiber surface with graphene oxide solution in a graphene oxide solution feeding syringe, on a PVDF nanofiber mat formed on a rotating drum by electrospray method, with the help of a high voltage source in the voltage range of 10-40 kV; and
soaking the graphene oxide coated nanofiber surface in hydrazine hydrate solution for the conversion of the graphene oxide coated nanofiber surface to the reduced graphene oxide coated nanofiber surface after the graphene oxide coating process.

2. An electrode production method according to claim 1, comprising, exposing the PVDF nanofiber mat formed on the rotating drum to the solution from a distance of 8 cm with a solution feed rate of 30 mL/h in the potential difference provided by the high voltage source in the step of producing the graphene oxide coated nanofiber surface by electrospray method.

3. An electrode production method according to claim 1, wherein in the graphene oxide coating step with the electrospray method on the PVDF nanofiber mat, the graphene oxide solution in the graphene oxide solution feeding syringe contains the graphene oxide solution that is mixed with 0.5 mg/mL of graphene oxide produced by Hummers' method in a solvent containing deionized water and 2-propanol by volume.

4. An electrode production method according to claim 3, wherein the Hummer's method comprises the steps of:
dispersing 1 gram of graphite powder into 120 mL of concentrated sulfuric acid and 13.3 mL of concentrated phosphoric acid mixture,
adding 6 grams of potassium permanganate into graphite-acid mixture and maintaining of the reaction for 12 hours at 50° C.,
pouring 120 mL of ice on the mixture obtained after 12 hours,
adding 1 ml of hydrogen peroxide in order to eliminate the excess amount of potassium permanganate,
separating solid graphene oxide and supernatant by centrifugation,
repeating the centrifugation process at least once, by washing the solid material separately with ethyl alcohol and HCl between the centrifugation processes.

5. An electrode production method according to claim 1, wherein said hydrazine hydrate solution, which enables the conversion of the graphene oxide coated nanofiber surface to the reduced graphene oxide coated nanofiber surface after the graphene oxide coating process, is 0.3 molar.

6. An electrode, which increases the mechanical stress resistance of the reduced graphene oxide-coated nanofibrous structure as a result of the reduced graphene oxide-coated nanofibrous structure tightly wrapping the PVDF nanofiber mat of the reduced graphene oxide coating and increases the output voltage and output current obtained from nanogenerators by the same tightly wrapping structure is used to increase the interface area of the PVDF nanofiber mat with reduced graphene oxide coating, is obtained by claim 1.

7. A piezoelectric nanogenerator with a graphene electrode comprising a graphene electrode socket in the middle of spacer paper positioned between two aluminum electrodes and an electrode according to claim 6 placed in the said graphene electrode socket.
